(19) United States
(12) Patent Application Publication
(10) Pub. No.: US 2023/0333141 A1
(43) Pub. Date: Oct. 19, 2023

(54) CONDUCTIVE PROBE, METHOD OF MANUFACTURING THE SAME, AND PROBE CARD DEVICE HAVING THE SAME

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Chih-Chieh LIAO, HSINCHU CITY (TW); Chih-Feng CHENG, HSINCHU CITY (TW); Yu-Min SUN, HSINCHU CITY (TW)

(21) Appl. No.: 17/804,090

(22) Filed: May 25, 2022

(30) Foreign Application Priority Data
Apr. 18, 2022 (TW) 111114644

(51) Int. Cl. G01R 1/067; G01R 3/00; G01R 1/073

(52) U.S. Cl. CPC G01R 1/06738; G01R 3/00; G01R 1/07314

(57) ABSTRACT

A conductive probe includes a columnar body. The columnar body is defined with a longitudinal direction. The columnar body is provided with a first contacting surface and a second contacting surface in the longitudinal direction. The first contacting surface is opposite to the second contacting surface, and the first contacting surface is cross shaped or X-shaped for contacting to a conductive pillar of a device under test (DUT).

### RELATED APPLICATIONS

This application claims priority to Taiwan Application Serial Number 111114644, filed on Apr. 18, 2022, which is herein incorporated by reference.

### BACKGROUND

### Field of Disclosure

The present disclosure relates to a conductive probe. More particularly, the present disclosure relates to a conductive probe having a cross shaped end surface, a method of manufacturing the same, and a probe card device having the same.

### Description of Related Art

In general, a semiconductor element, for example a die or a wafer, is moved into a test platform during a Chip Probe (CP) testing stage. Next, probes of the probe card located above the test platform can be controlled to descend for touching conductive pillars of the semiconductor element so as to perform electrical inspection on the semiconductor element.

However, when the conductive pillars of the semiconductor element are respectively touched by the probes of the probe card one by one, each of the probes may inevitably press the top surface of the corresponding conductive pillar to punch a probe mark (e.g., scratch or dent) with a specific size on the corresponding conductive pillar. If the size of the probe mark is so large, the conduction efficiency of each of the conductive pillars will be reduced thereby affecting the reliability of the semiconductor element.

It is noted that the above-mentioned technology obviously still has inconvenience and defects, and needs to be further improved. Therefore, how to develop a solution to improve the foregoing deficiencies and inconvenience is an important issue that relevant persons engaged in the industry are currently unable to delay.

### SUMMARY

One aspect of the present disclosure is to provide a conductive probe, a method of manufacturing the same, and a probe card device having the same.

In one embodiment of the present disclosure, a conductive probe is provided, and the conductive probe includes a columnar body that is defined with a longitudinal direction. The columnar body is provided with a first contacting surface and a second contacting surface which are opposite to each other along the longitudinal direction. The first contacting surface is cross shaped or X-shaped for contacting a conductive pillar of a device under test (DUT).

In one embodiment of the present disclosure, a conductive probe is provided, and the conductive probe includes a first segment. The first segment includes a middle-shaft body, two first lateral wings and two second lateral wings. The middle-shaft body has a longitudinal direction. The first lateral wings are respectively disposed on two opposite sides of the middle-shaft body and collectively extend along the longitudinal direction. The second lateral wings are respectively disposed on another two opposite sides of the middle-shaft body and collectively extend along the longitudinal direction. One of the first lateral wings is disposed between the second lateral wings, one of the second lateral wings is disposed between the first lateral wings. The middle-shaft body, the first lateral wings and the second lateral wings collectively form a contacting surface along the longitudinal direction. The contacting surface is used to contact a conductive pillar of a device under test (DUT).

In one embodiment of the present disclosure, a probe card device is provided, and the probe card device includes a circuit board, a probe module, a space transforming layer and at least one conductive probe mentioned above. The circuit board has a plurality of contacts. The probe module includes a probe loading base and a plurality of positioning openings arranged in an array on the probe loading base. Each of the positioning openings is penetrated through the probe loading base. The space transforming layer is located between the circuit board and the probe module. The space transforming layer includes a plurality of circuit routes. The conductive probe is fixedly held in one of the positioning openings, and electrically connected to one of the contacts through one of the circuit routes.

In one embodiment of the present disclosure, a method of manufacturing a conductive probe is provided, the method includes several steps as follows. A substrate is provided. A first photoresist layer is formed on the substrate. The first photoresist layer is etched to form a first columnar groove thereon. A first metal layer is formed in the first columnar groove and on the first photoresist layer. A second photoresist layer is formed on one surface of the first metal layer opposite to the substrate. The second photoresist layer is etched to form a second columnar groove thereon. A second metal layer is formed in the second columnar groove to be integrally formed as a conductive probe with the first metal layer. The substrate, the first photoresist layer and the second photoresist layer are removed to obtain the conductive probe, and a cross section of the conductive probe is in a cross shape.

Thus, through the construction of the embodiments above, the conductive probe of the disclosure is able to reduce the size of the probe mark caused on the conductive pillar, thereby avoiding reducing the conduction efficiency of the conductive probe and the reliability of the semiconductor element.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a perspective view of a conductive probe according to one embodiment of the present disclosure.

FIG. 2A is a partial side view of the conductive probe of FIG. 1 contacting a conductive pillar of a DUT.

FIG. 2B is a top view of FIG. 2A.

FIG. 3 is a perspective view of a conductive probe according to one embodiment of the present disclosure.

FIG. 4A is a perspective view of a conductive probe according to one embodiment of the present disclosure.

FIG. 4B is a partial side view of the conductive probe of FIG. 4A contacting a conductive pillar of a DUT.

FIG. 5 is a perspective view of a conductive probe according to one embodiment of the present disclosure.

FIG. 6A is a schematic view of a probe card device according to one embodiment of the present disclosure.

FIG. 6B is a front view of a probe loading base of FIG. 6A.

FIG. 7 is a flow chart of a method of manufacturing a conductive probe according to one embodiment of the present disclosure.

FIG. 8A to FIG. 8H are operational schematic views of the steps of FIG. 7.

### DESCRIPTION OF THE EMBODIMENTS

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

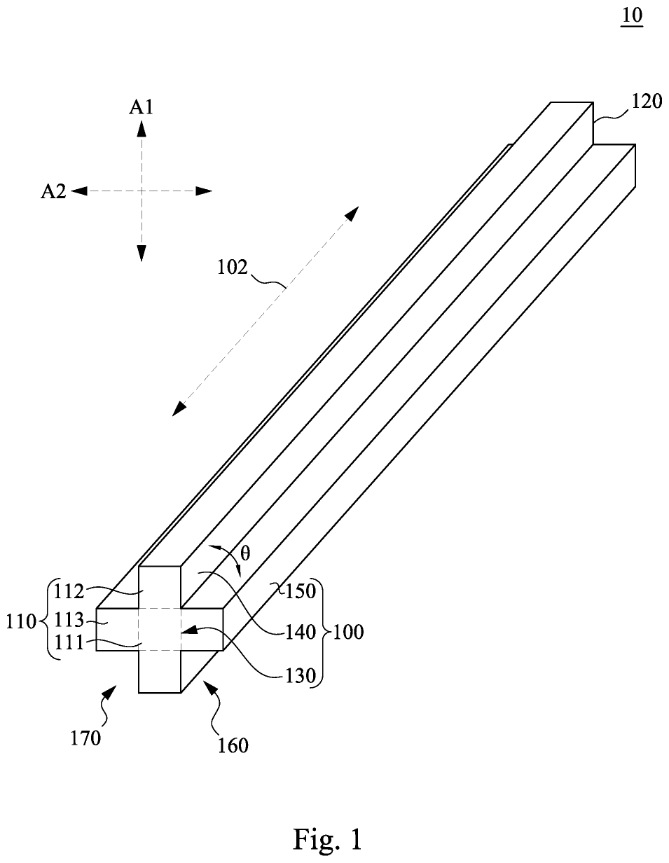

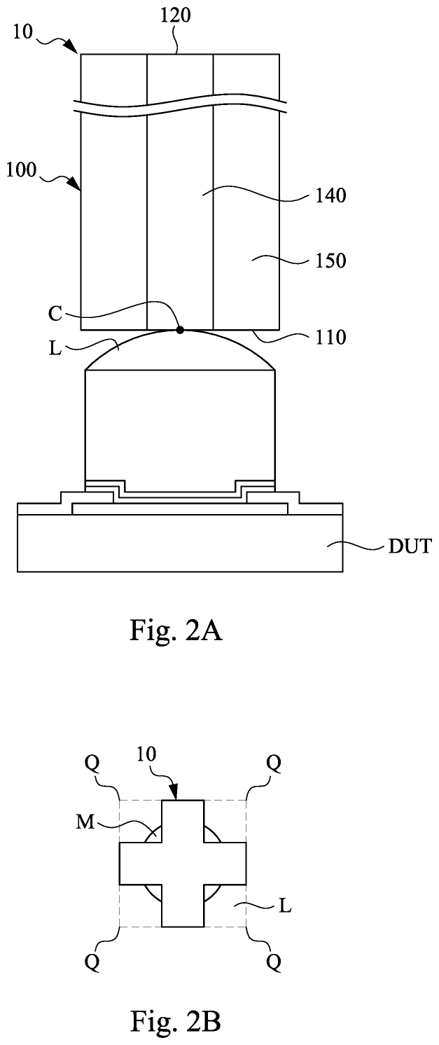

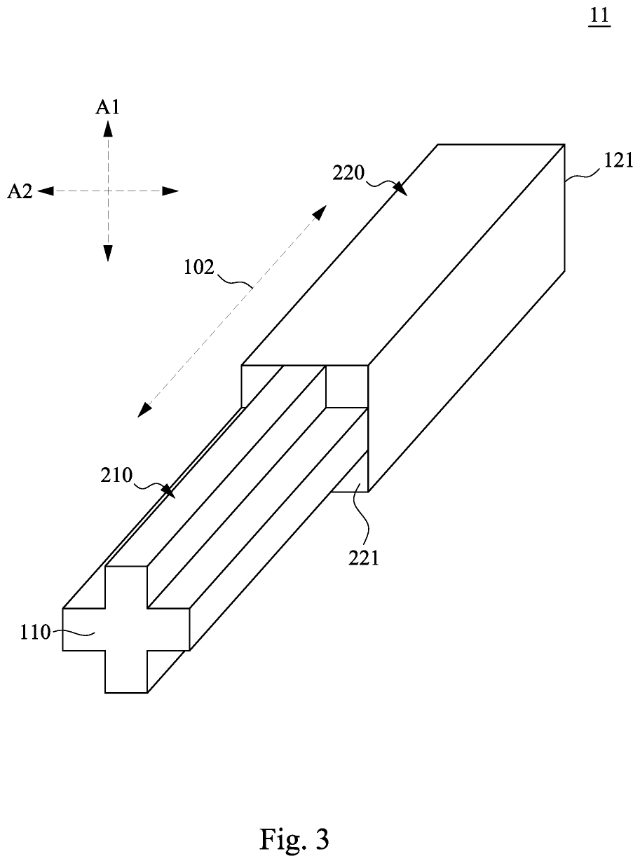

Reference is now made to FIG. 1 to FIG. 2B, in which FIG. 1 is a perspective view of a conductive probe 10 according to one embodiment of the present disclosure, FIG. 2A is a partial side view of the conductive probe 10 of FIG. 1 contacting a conductive pillar L of a DUT, and FIG. 2B is a top view of FIG. 2A. As shown in FIG. 1 to FIG. 2B, the conductive probe 10 includes a columnar body 100 that is defined with a longitudinal direction 102. The columnar body 100 is provided with a first contacting surface 110 and a second contacting surface 120 in the longitudinal direction 102, and the first contacting surface 110 and the second contacting surface 120 are opposite to each other. The first contacting surface 110 is cross shaped. Thus, when the conductive probe 10 contacts a device under test (DUT), the DUT is a semiconductor element such as a die or a wafer, the conductive probe 10 physically contacts one of the conductive pillars L (e.g., copper pillar) of the DUT through the first contacting surface 110 so as to form a specific size of a probe mark M on the top arc surface of the conductive pillar L. In this embodiment, for example, the conductive probe 10 is a small-sized micro-probe processed by a MEMS process, however, the disclosure is not limited thereto.

Therefore, since the design of the cross shaped end surface of the conductive probe 10 can constrain the expansion of the probe mark M in the four quadrants Q in FIG. 2B, the conductive probe 10 of this embodiment not only reduces the contact area of the conductive pillar L being contacted by the conductive probe 10 so as to reduce the size (e.g., area reduction rate of 44.4%) of the probe mark M formed on the top arc surface of the conductive pillar L, but also improves the conduction efficiency of the conductive probe and the reliability of the semiconductor element.

For example, as the size of the probe mark on the conductive pillar L formed by the conventional shape of the conventional probe is 25-36% of the total area of the conductive pillar L, the first contacting surface 110 of the disclosure with a cross shaped section can reduce the size of the probe mark M to 23-32%, that is, an improvement of 2-4% is obtained. In this way, because the smaller the size of the probe marks M, the less residues scratched from the coating layer on the top arc surface of the conductive pillars L are, and the less chance of the residues falling off, the less the material loss of the coating layer on the top arc surface of the conductive pillars L so as to remain the electrical conductivity of the conductive probe 10 and the reliability of the semiconductor element.

Specifically, the first contacting surface 110 includes a central area 111, two first extension areas 112 and two second extension areas 113. The first extension areas 112 respectively extend outward from two opposite ends of the central area 111, and extend coaxially along a first axis A1 that is orthogonal to the longitudinal direction 102. The second extension areas 113 respectively extend outward from another two opposite ends of the central area 111, and extend coaxially along a second axis A2 that is intersected the first axis A1, and orthogonal to the longitudinal direction 102. One of the first extension areas 112 is disposed between the second extension areas 113, and one of the second extension areas 113 is disposed between the first extension areas 112. An included angle θ between one of the first extension areas 112 and one of the second extension areas 113 is substantially 90° (i.e., right angle), and the first axis A1 and the second axis A2 are orthogonal to each other. The central area 111, the first extension areas 112 and the second extension areas 113 are respectively rectangular, so as to form the above-mentioned cross shaped end surface together. Therefore, when the conductive probe 10 contacts the conductive pillar L of the DUT, since the vertex C of the conductive pillar L corresponds to the central area 111 of the first contacting surface 110, the first extension areas 112 and the second extension areas 113 of the conductive probe 10 can symmetrically contact the corresponding areas of the top arc surface of the conductive pillar L, respectively, thereby providing anti-slip effect from the top arc surface of the conductive pillar L.

For example, in this embodiment, the columnar body 100 is a cross-typed column extending along a straight line, that is, any cross section of the columnar body 100 is cross shaped. More specifically, the conductive probe 10 includes a middle-shaft body 130, two first lateral wings 140 and two second lateral wings 150. The middle-shaft body 130 is with the aforementioned longitudinal direction 102. The first lateral wings 140 are respectively disposed on two opposite sides of the middle-shaft body 130 and collectively extend along the longitudinal direction 102. The second lateral wings 150 are respectively disposed on another two opposite sides of the middle-shaft body 130 and collectively extend along the longitudinal direction 102. One of the first lateral wings 140 is disposed between the second lateral wings 150, one of the second lateral wings 150 is disposed between the first lateral wings 140. The middle-shaft body 130, the first lateral wings 140 and the second lateral wings 150 collectively form the first contacting surface 110 mentioned above. In other words, the columnar body 100 includes two first depression portions 160 and two second depression portions 170. The first depression portions 160 are respectively recessed on one side of the columnar body 100 and extend along the longitudinal direction 102. The second depression portions 170 are respectively recessed on the other side of the columnar body 100 and extend along the longitudinal direction 102. The first contacting surface 110 is defined by one end surface of the columnar body 100 through the first depression portions 160 and the second depression portions 170 collectively. An included angle θ between one of the first lateral wings 140 and the neighboring one of the second lateral wings 150 is substantially 90° (i.e., right angle).

Thus, if the current flow inside the conductive probe 10 is not evenly distributed, the current flow on the conductive probe 10 will be concentrated on the surfaces of the conductive probe 10 according to the Skin Effect. Therefore, since the conductive probe 10 of the embodiment is a cross shaped or X-shaped column, compared with the conventional rectangular column design, the total surface area of the conductive probe 10 of the embodiment is not increased, so as not affect the current flow of the conductive probe 10.

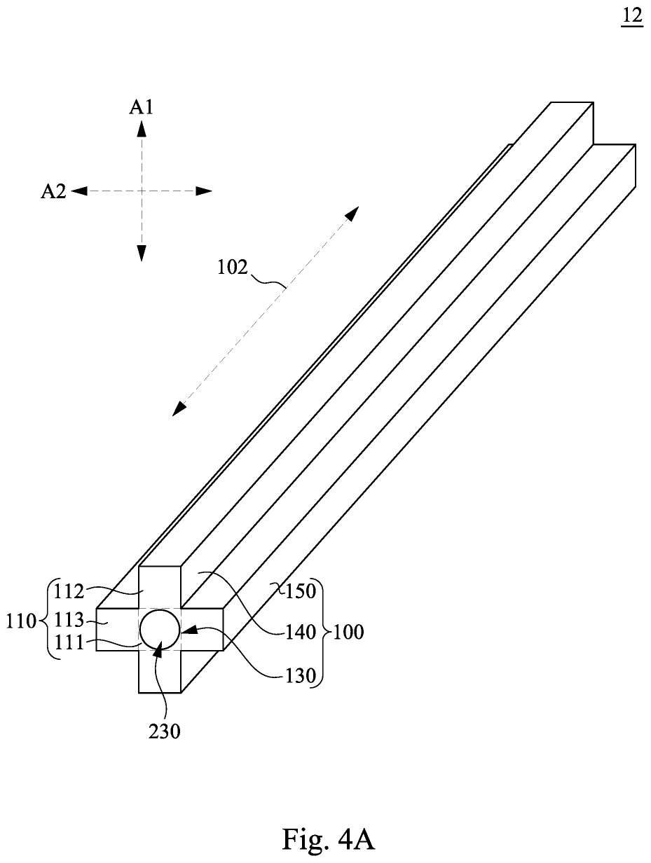

FIG. 3 is a perspective view of a conductive probe 11 according to one embodiment of the present disclosure. As shown in FIG. 3, the conductive probe 11 of the embodiment is substantially the same as the conductive probe 10 of FIG. 1, except that the conductive probe 11 further includes a second segment 220 connected to the aforementioned cross-typed column (called first segment 210 hereinafter), and coaxial to the first segment 210. In other words, the above-mentioned cross-typed column (called first segment 210 hereinafter) is connected to the end surface 221 of the second segment 220 opposite to the second contacting surface 121, and the aforementioned longitudinal direction 102 can be the axis of the first segment 210 and the second segment 220.

The appearance of the second segment 220 is different from the appearance of the first segment 210. For example, the second segment 220 is a rectangular column extending along a straight line, that is, any cross section of the second segment 220 is rectangular, and the second contacting surface 121 is a rectangular end face of the second segment 220 being opposite to the first segment. In this way, since the overall structure of the conductive probe 11 of the embodiment is not cross-typed, the overall structural strength of the conductive probe 11 can be relatively improved.

Furthermore, in order to improve the structural strength of the conductive probe 11, in the embodiment, the length ratio of the first segment 210 and the second segment 220 is 3:7 or 2:8. However, the disclosure is not limited to the length ratio of the first segment 210 and the second segment 220, and those with ordinary skill of the disclosure may adjust the length ratio of the first segment 210 and the second segment 220 according to actual demands or limitations.

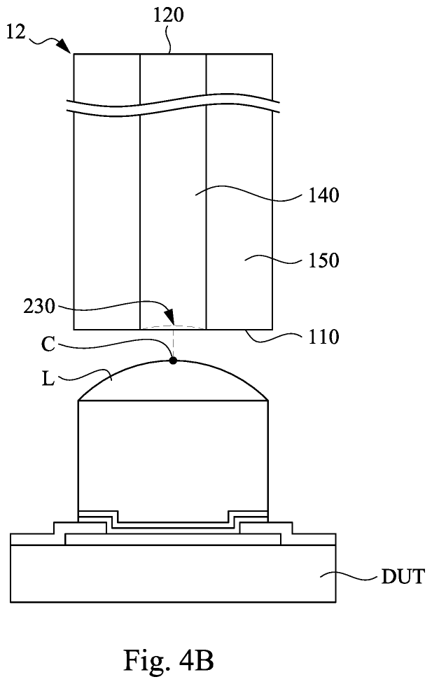

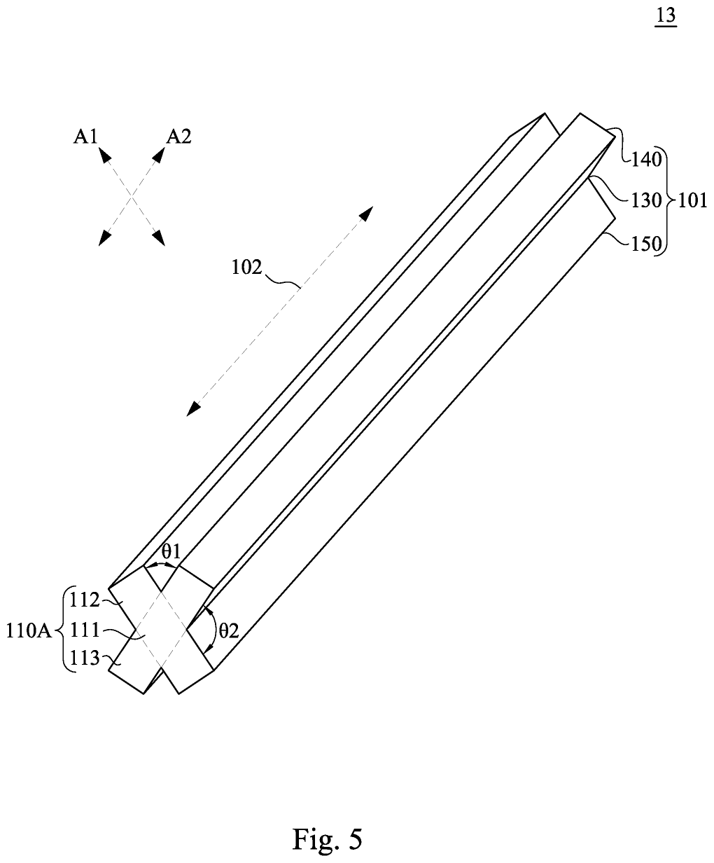

FIG. 4A is a perspective view of a conductive probe 12 according to one embodiment of the present disclosure. FIG. 4B is a partial side view of the conductive probe 12 of FIG. 4A contacting a conductive pillar L of a DUT. As shown in FIG. 4A and FIG. 4B, the conductive probe 12 of the embodiment is substantially the same as the conductive probe 10 of FIG. 1, except that the first contacting surface 110 of the conductive probe 12 is further formed with a curved concave portion 230. The most of the curved concave portion 230 is mainly disposed in the central area 111 and recessed towards the second contacting surface 120. Therefore, when the first contacting surface 110 of the conductive probe 12 contacts the conductive pillar L of the DUT, the curved concave portion 230 of the first contacting surface 110 is able to receive a part of the conductive pillar L. Thus, not only does the central area 111 of the first contacting surface 110 be positioned to the vertex C of the conductive pillar L more easily, but also the possibility of the conductive probe 12 being moved away from the conductive pillar L because of sliding can be reduced. However, the disclosure is not limited thereto, and in other embodiments, the conductive probe 12 of the embodiment may also be added with the second segment 220 as described in FIG. 3.

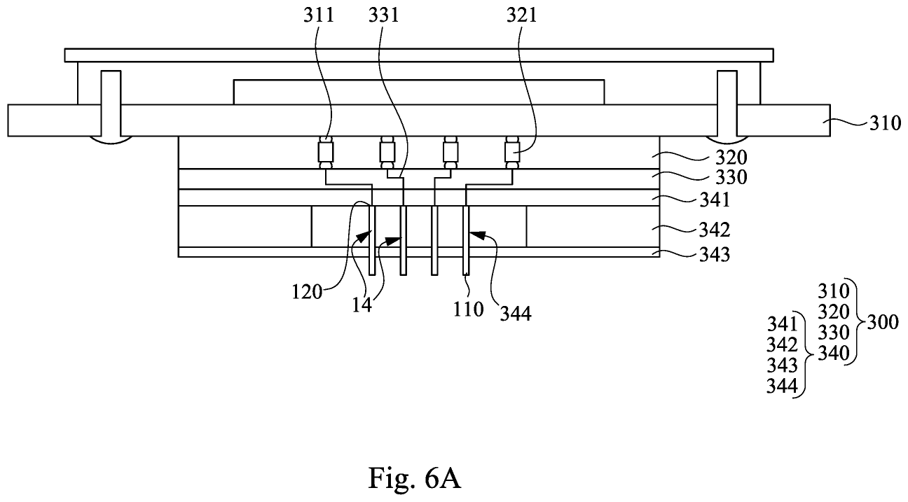

FIG. 5 is a perspective view of a conductive probe 13 according to one embodiment of the present disclosure. As shown in FIG. 5, the conductive probe 13 of the embodiment is substantially the same as the conductive probe 10 of FIG. 1, except that comparing to the columnar body 100 being as a cross column in FIG. 1, the columnar body 101 of the embodiment is an X-shaped column, any cross section of the columnar body 101 is X-shaped, and the first contacting surface 110A is X-shaped.

More specifically, the first axial direction A1 and the second axial direction A2 are intersected with each other, but are not orthogonal to each other. The included angle θ1 between the first lateral wing 140 and one of the second lateral wings 150 is an acute angle, the included angle θ2 with the other second lateral wing 150 is an obtuse angle, and the included angle θ1 between the first extension area 112 and the second extension area 113 is an acute angle, and the included angle θ2 of the other second extension area 113 is an obtuse angle. However, the disclose is not limited thereto, and in other embodiments, the conductive probe 13 of the embodiment may also be added with the second segment 220 as described in FIG. 3.

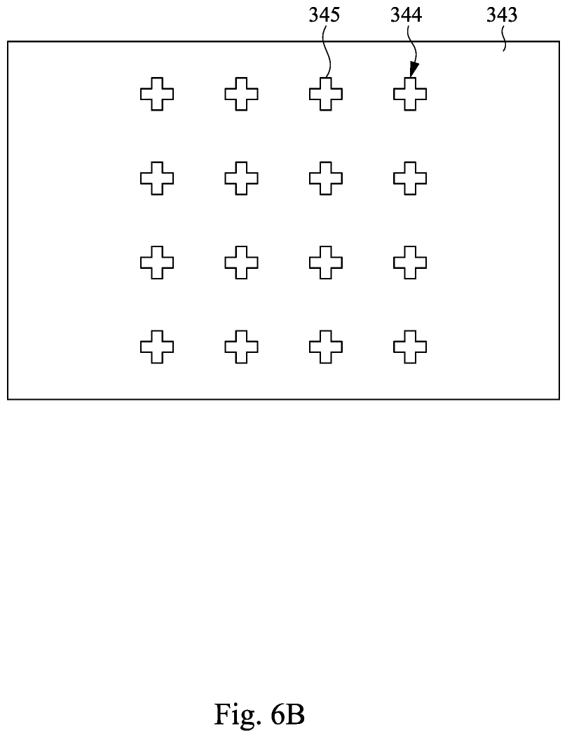

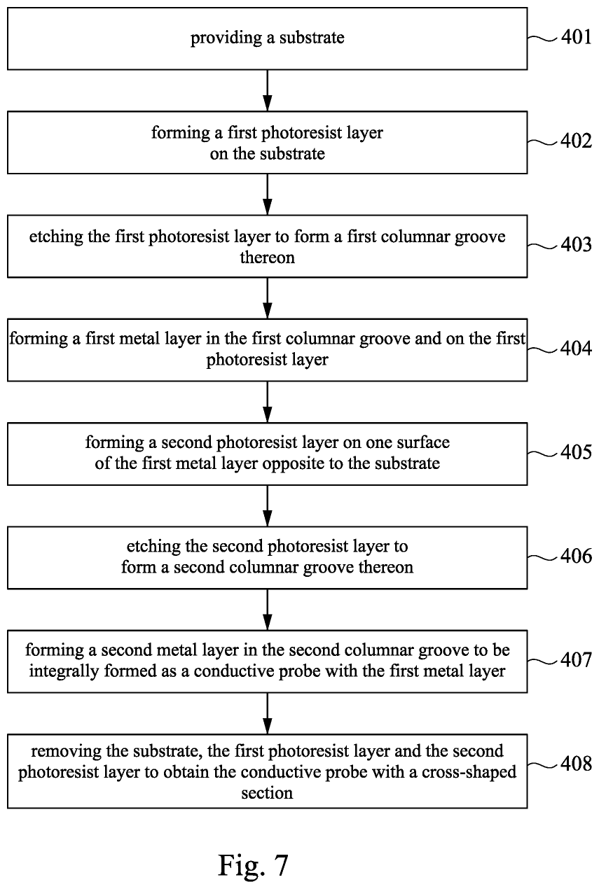

FIG. 6A is a schematic view of a probe card device 300 according to one embodiment of the present disclosure. FIG. 6B is a front view of a probe loading base 343 of FIG. 6A. As shown in FIG. 6A and FIG. 6B, the probe card device 300 includes a circuit board 310, an intermediary layer 320, a space transforming layer 330, a probe module 340 and a plurality of conductive probes 14. The circuit board 310 is provided with a plurality of contacts 311 spaced arranged on the circuit board 310. The intermediary layer 320 is disposed between the circuit board 310 and the space transforming layer 330, and the intermediary layer 320 is provided with a plurality of conductive paths 321 which are spaced arranged thereon. Each of the conductive paths 321 is electrically connected to one of the contacts 311. The space transforming layer 330 is located between the intermediary layer 320 and the probe module 340, and the space transforming layer 330 is provided with a plurality of circuit routes 331 which are spaced arranged thereon. Each of the circuit routes 331 is electrically connected to one of the conductive paths 321. The probe module 340 includes an upper guide plate 341, a lower guide plate 342, a probe loading base 343 and a plurality of positioning openings 344. The probe loading base 343 is sandwiched between the upper guide plate 341 and the lower guide plate 342. The positioning openings 344 are arranged in an array on the probe loading base 343, and each of the positioning openings 344 is penetrated through the probe loading base 343. Each of the conductive probes 14 is fixedly held in one of the positioning openings 344. The second contacting surface 120 of each of the conductive probes 14 is electrically connected to one of the circuit routes 331, and electrically connected to one of the contacts 311 through the corresponding circuit route 331. The first contacting surface 110 is used to electrically connect to the conductive pillar L of DUT (FIG. 2). It is noted, the second contacting surface 120 only needs to be directly contacted to the circuit routes 331 and does not need to be soldered to the circuit routes 331 through soldering materials.

More specifically, the positioning openings 344 is in a cross shape, and the size of the positioning opening 344 is not greater than the size of the columnar body 100, so that the columnar body 100 is directly clamped by two opposite inner walls 345 of the positioning opening 344 and held on the probe loading base 343. However, the disclosure is not limited thereto, and in other embodiments, the positioning opening 344 may also be in an X shape or a rectangular shape.

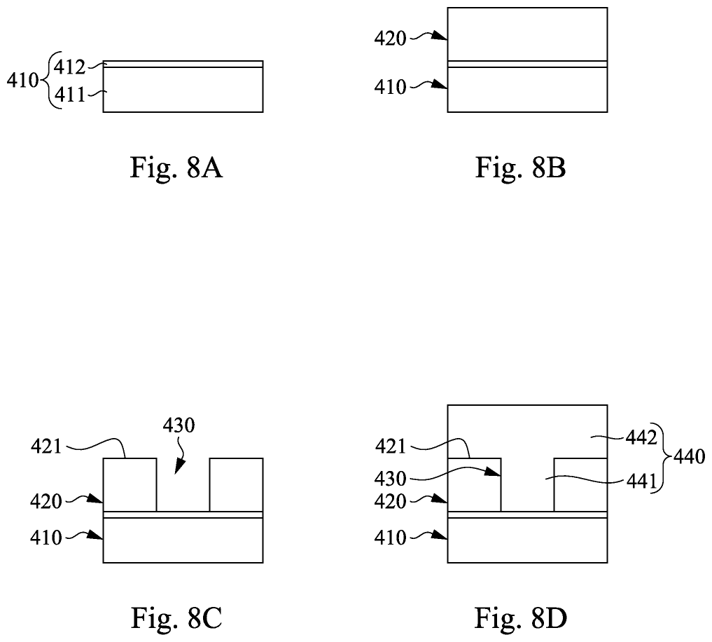

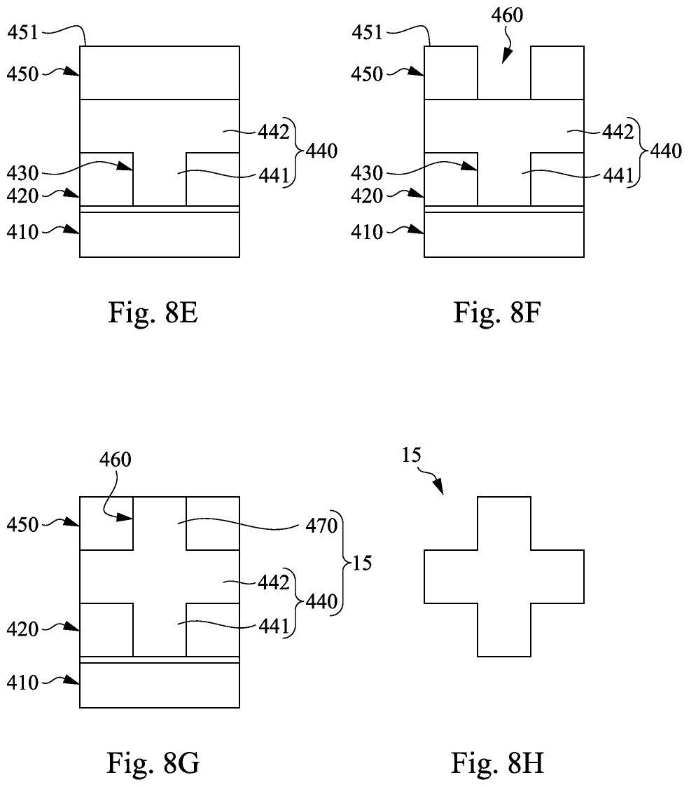

FIG. 7 is a flow chart of a method of manufacturing a conductive probe according to one embodiment of the present disclosure. FIG. 8A to FIG. 8H are operational schematic views of the steps of FIG. 7. As shown in FIG. 7 and FIG. 8A to FIG. 8H, the method of manufacturing a conductive probe includes step 401 to step 408 as follows.

In step 401, a substrate 410 is provided (FIG. 8A). In step 402, a first photoresist layer 420 is formed on one surface of the substrate 410 (FIG. 8B). In step 403, the first photoresist layer 420 is etched to form a first columnar groove 430 thereon (FIG. 8C). In step 404, a first metal layer 440 is formed in the first columnar groove 430 and on the first photoresist layer 420 (FIG. 8D). In step 405, a second photoresist layer 450 is formed on one surface 451 of the first metal layer 440 opposite to the substrate 410 (FIG. 8E). In step 406, the second photoresist layer 450 is etched to form a second columnar groove 460 thereon (FIG. 8F). In step 407, a second metal layer 470 is formed in the second columnar groove 460 to be integrally formed as a conductive probe 15 with the first metal layer 440 (FIG. 8G). In step 408, the substrate 410, the first photoresist layer 420 and the second photoresist layer 450 are removed to obtain the conductive probe 15, and a cross section of the conductive probe 15 is in a cross shape (FIG. 8G and FIG. 8H).

As shown in FIG. 8A, in step 401, more specifically, a metal coating layer 412 is formed on an outer surface of a silicon substrate 411 through an electroplating process to form the substrate 410. As shown in FIG. 8C, in step 403, more specifically, one surface 421 of the first photoresist layer 420 opposite to the substrate 410 is etched to form the first columnar groove 430 through exposure, development and etching of photolithography, and the first columnar groove 430 is linear to extend along the above-mentioned longitudinal direction 102 (refer to FIG. 1), and any cross-section of the first columnar groove 430 is rectangular. As shown in FIG. 8D, in step 404, more specifically, one part 441 of the first metal layer 440 completely fills into the first columnar groove 430, and the other part 442 of the first metal layer 440 covers the surface 421 of the first photoresist layer 420 opposite to the substrate 410. As shown in FIG. 8F, in step 406, more specifically, one surface 451 of the second photoresist layer 450 opposite to the substrate 410 is etched to form the second columnar groove 460 through exposure, development and etching of photolithography, and the second columnar groove 460 is linear to extend along the above-mentioned longitudinal direction 102 (refer to FIG. 1). Any cross-section of the second columnar groove 460 is rectangular, and the second columnar groove 460 is parallel to the first columnar groove 430, and the size of the second columnar groove 460 is equal to the size of the first columnar groove 430. As shown in FIG. 8G, in step 407, more specifically, the second metal layer 470 completely fills into the second columnar groove 460, and the second metal layer 470 is only disposed within the second columnar groove 460.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

1-16. (canceled)

17. A probe card device, comprising:
a circuit board having a plurality of contacts;
a probe module comprising a probe loading base and a plurality of positioning openings arranged in an array on the probe loading base, and each of the positioning openings is penetrated through the probe loading base;
a space transforming layer located between the circuit board and the probe module, and the space transforming layer comprising a plurality of circuit routes; and
a conductive probe that is fixedly held in one of the positioning openings, the conductive probe comprising a columnar body that is defined with a longitudinal direction, and the columnar body that is provided with a first contacting surface and a second contacting surface which are opposite to each other along the longitudinal direction, and the second contacting surface electrically connected to one of the contacts through one of the circuit routes, wherein the first contacting surface is cross shaped or X-shaped for contacting a conductive pillar of a device under test (DUT).

18. The probe card device of claim 17, wherein the columnar body is directly clamped by two opposite inner walls of the one of the positioning openings and held on the probe loading base.

19. The probe card device of claim 17, wherein the positioning openings are respectively cross shaped, X-shaped or rectangular.

20. (canceled)

21. The probe card device of claim 17, wherein the first contacting surface comprising:
a central area;
two first extension areas respectively extending outward from two opposite ends of the central area, and extending coaxially along a first axis that is orthogonal to the longitudinal direction; and
two second extension areas respectively extending outward from another two opposite ends of the central area, and extending coaxially along a second axis that is intersected the first axis, and orthogonal to the longitudinal direction,
wherein one of the first extension areas is disposed between the second extension areas, and one of the second extension areas is disposed between the first extension areas.

22. The probe card device of claim 21, wherein an included angle between the one of the first extension areas and the one of the second extension areas is a right angle, and the first axis and the second axis are orthogonal to each other.

23. The probe card device of claim 21, wherein an included angle between the one of the first extension areas and the one of the second extension areas is an obtuse angle, and an included angle between the one of the first extension areas and the other of the second extension areas is an acute angle.

24. The probe card device of claim 21, wherein the columnar body is further formed with a curved concave portion in the central area for receiving a part of the conductive pillar.

25. The probe card device of claim 17, wherein the columnar body is a cross-typed column, wherein a cross section of the columnar body is cross shaped.

26. The probe card device of claim 17, wherein the columnar body is composed of a first segment and a second segment coaxially connected to each other, a cross section of the first segment is cross shaped, and a shape of the cross section of the first segment is different from a shape of a cross section of the second segment, wherein the first contacting surface is an end surface of the first segment, and the second contacting surface is an end surface of the second segment.

27. The probe card device of claim 26, wherein a length ratio of the first segment and the second segment is 3:7 or 2:8.

28. The probe card device of claim 17, wherein the columnar body comprises:
two first depression portions respectively recessed on one side of the columnar body and extending along the longitudinal direction; and
two second depression portions respectively recessed on the other side of the columnar body and extending along the longitudinal direction,
wherein the first contacting surface is defined by one end surface of the columnar body through the first depression portions and the second depression portions collectively.

29. A probe card device, comprising:
a circuit board having a plurality of contacts;
a probe module comprising a probe loading base and a plurality of positioning openings arranged in an array on the probe loading base, and each of the positioning openings is penetrated through the probe loading base;
a space transforming layer located between the circuit board and the probe module, and the space transforming layer comprising a plurality of circuit routes; and
a conductive probe that is fixedly held in one of the positioning openings, and electrically connected to one of the contacts through one of the circuit routes, the conductive probe comprising a first segment, and the first segment comprising a middle-shaft body having a longitudinal direction; two first lateral wings respectively disposed on two opposite sides of the middle-shaft body and collectively extending along the longitudinal direction; and two second lateral wings respectively disposed on another two opposite sides of the middle-shaft body and collectively extending along the longitudinal direction,
wherein one of the first lateral wings is disposed between the second lateral wings, one of the second lateral wings is disposed between the first lateral wings, the middle-shaft body, the first lateral wings and the second lateral wings collectively form a contacting surface along the longitudinal direction, the contacting surface is used to contact a conductive pillar of a device under test (DUT).

30. The probe card device of claim 29, wherein an included angle between the one of the first lateral wings and the one of the second lateral wings is a right angle.

31. The probe card device of claim 29, wherein an included angle between the one of the first lateral wings and the one of the second lateral wings is an obtuse angle, and an included angle between the one of the first lateral wings and the other of the second lateral wings is an acute angle.

32. The probe card device of claim 29, wherein the first segment is further formed with a curved concave portion on the contacting surface for receiving a part of the conductive pillar.

33. The probe card device of claim 29, wherein the contacting surface is cross shaped or X-shaped.

34. The probe card device of claim 29, further comprising:
a second segment coaxially connected to the first segment, wherein a cross section of the second segment is rectangular.

35. The conductive probe of claim 34, wherein a length ratio of the first segment and the second segment is 3:7 or 2:8.
